(19) United States
(12) Patent Application Publication
(10) Pub. No.: US 2012/0307474 A1
(43) Pub. Date: Dec. 6, 2012

(54) DISPLAY DEVICE

(76) Inventor: Kazuo WATANABE, Kokubunji-shi (JP)

(21) Appl. No.: 13/308,337

(22) Filed: Nov. 30, 2011

(30) Foreign Application Priority Data
May 31, 2011 (JP) 2011-122963

(51) Int. Cl. H05K 7/02

(52) U.S. Cl. 361/807

(57) ABSTRACT

In one embodiment, there is provided a display device. The display device includes: a main body including a display panel; and a stand including: a support configured to support the main body; and a pedestal having a first surface and a second surface opposite to the first surface, wherein the support is disposed on the first surface of the pedestal. At least one groove is formed on the first surface of the pedestal.

This application claims priority from Japanese Patent Application No. 2011-122963, filed on May 31, 2011, the entire contents of which are hereby incorporated by reference.

### BACKGROUND

1. Field

Embodiments described herein relate to a display device having a main body that is supported by a stand.

2. Description of the Related Art

With an advance to a large-sized display device using a display panel such as a liquid crystal display (LCD) panel or a plasma display panel (PDP) in recent years, display devices such as flat panel televisions of 40 inch type or more (40 inches or more in diagonal of an effective visible area) are becoming commercialized. A flat television has a rectangular flat screen which has an aspect ratio of 16:9 and is supported perpendicular to an installation surface. Such a flat screen is vulnerable to an external force or an earthquake.

A display device such as a flat television may be mounted on a stand supporting a main body of the display device, which is called a “stationary stand” or “desktop stand.” The stand includes a support that secures the main body by, for example, screws. There has been a method for securing a stand to an installation surface by screws or bands in order to prevent a display device from falling down.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention:

FIG. 1 is a schematic perspective view showing an example of a display device according to an exemplary embodiment;

FIG. 2 is an exterior perspective view showing a state where a band is removed from the display device shown in FIG. 1;

FIG. 3 is a perspective view showing an example of the stand according to the exemplary embodiment.

FIG. 4 is a perspective view showing another example of the stand;

FIG. 5 is a perspective view showing yet another example of the stand;

FIG. 6 is a sectional view showing a positional relationship between a pedestal of the stand shown in FIG. 5 and a securing band;

FIG. 7 is a perspective view showing yet another example of the stand;

FIG. 8 is a sectional view of the stand for explaining a shape of a groove;

FIG. 9 is a sectional view of the stand for explaining another shape of a groove;

FIG. 10 is a sectional view showing a state where a band is installed in the groove; and

FIG. 11 is a view showing an example of a projection in the groove.

### DETAILED DESCRIPTION

According to exemplary embodiments of the present invention, there is provided a display device. The display device includes: a main body including a display panel; and a stand including: a support configured to support the main body; and a pedestal having a first surface and a second surface opposite to the first surface, wherein the support is disposed on the first surface of the pedestal. At least one groove is formed on the first surface of the pedestal.

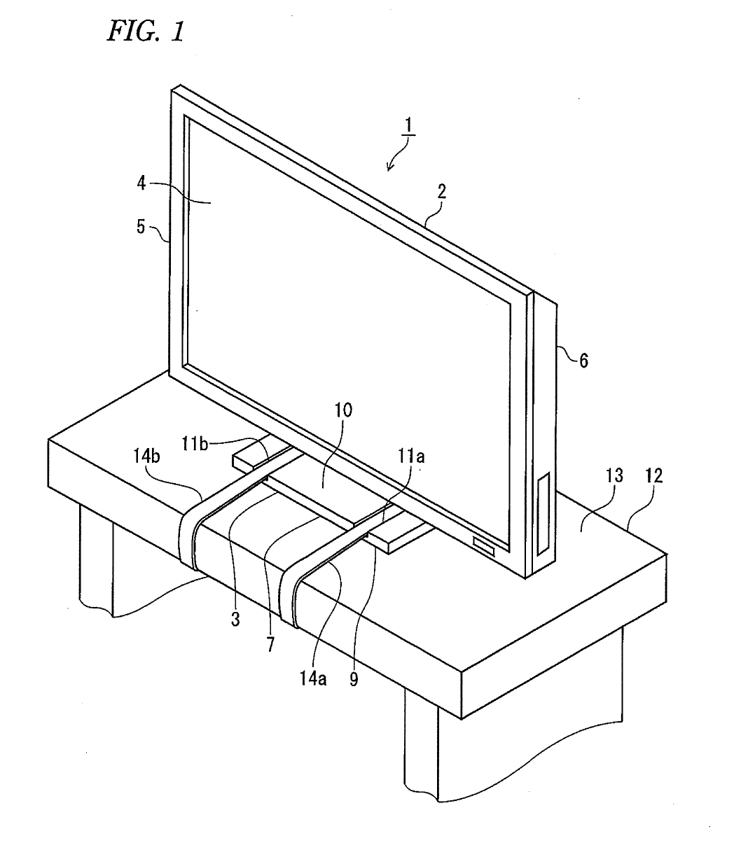

Hereinafter, exemplary embodiments will be described with reference to the drawings. FIG. 1 is a schematic perspective view showing an example of a display device according to an exemplary embodiment. A display device 1 may be, for example, a digital TV which is capable of receiving, recording and reproducing digital broadcasting programs, and that displays the images of the digital broadcasting programs on a screen.

The display device 1 includes a main body 2 and a stand 3 that supports the main body 2. The stand 3 includes a pedestal 7 and a support 8 to which the main body 2 is secured by, for example, screws. The main body 2 includes a display panel 4 such as a liquid crystal panel or a plasma display panel (PDP), that is arranged in the front side, and a frame (not shown) is provided in the rear side of the display panel 4 to support the display panel 4. The frame is provided with a power circuit (not shown) or a circuit board (not shown) for driving the display panel 4. The side in which the display panel 4 is exposed is referred to as a front side of the display device 1, and the opposite side thereof is referred to as a rear side of the display device 1.

The main body 2 is surrounded by a front cover 5 that covers the front side, a top surface, a bottom surface and a portion of both lateral surfaces of the main body 2. The main body 2 is also surrounded by a rear cover 6 that covers the rear side, the top surface, the bottom surface and a portion of the both lateral surfaces of the main body 2.

The display device 1 is mounted on an installation surface 13 of an installation board 12. Grooves 11a and 11b are formed on the top surface 10 of the pedestal 7, which is in the opposite side of the bottom surface 9 contacting the installation surface 13. The pedestal 7 is secured on the installation surface 13 by securing bands 14a and 14b. The bands 14a and 14b are received in the grooves 11a and 11b, respectively.

Since the bands 14a and 14b are received in the grooves 11a and 11b, respectively, the display device 1 will not be moved even when a vibration caused by, for example, an earthquake is applied to the installation board 12, thereby preventing the display device from falling down.

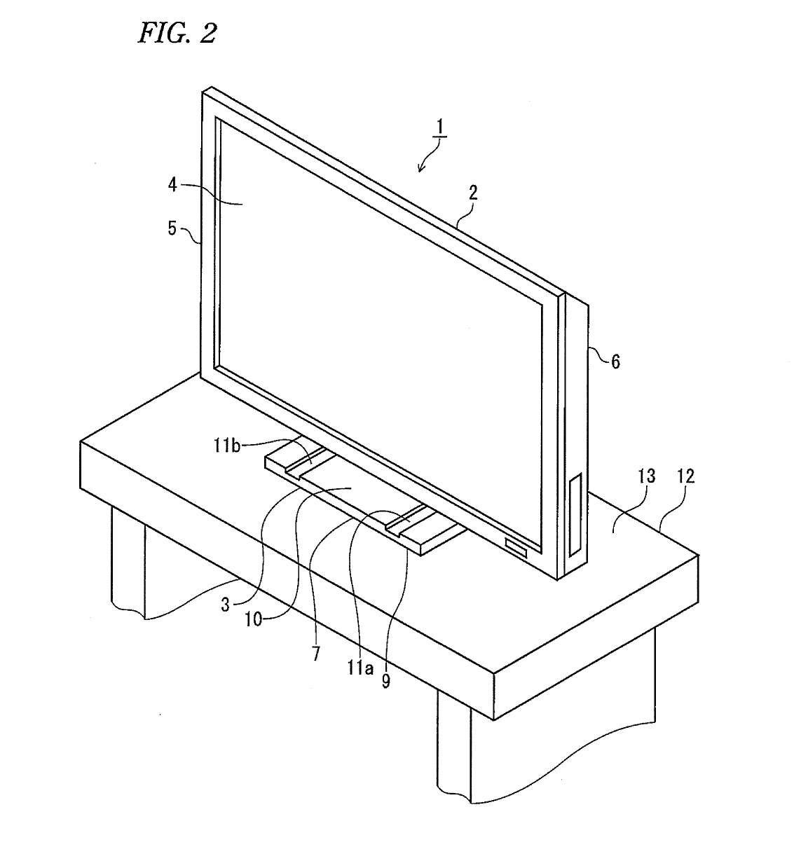

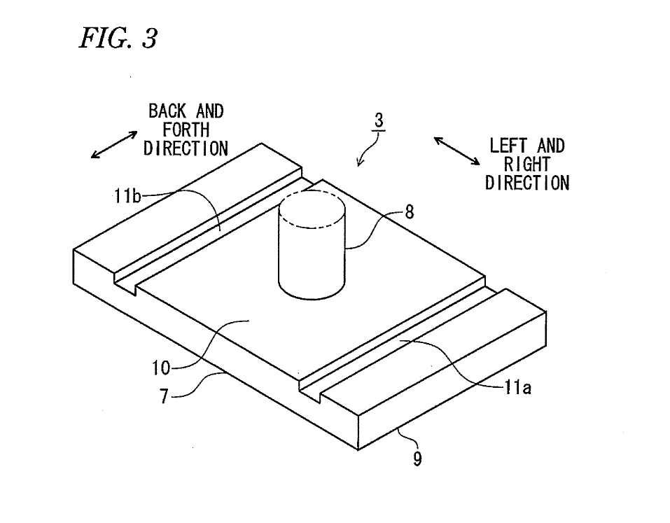

FIG. 2 is an exterior perspective view showing a state where the bands are removed from the display device 1 as shown in FIG. 1. FIG. 3 is a perspective view showing an example of the stand 3. The pedestal 7 has a rectangular flat shape and includes the support 8 for supporting the main body 2 in the central portion of the pedestal 7. Although it is shown in FIGS. 2 and 3 that the pedestal 7 is substantially rectangular, it may be circular, elliptical or polygonal. In addition, although it is shown in FIGS. 2 and 3 that the pedestal 7 is flat, it may have different thickness in its circumference and center. For example, it may be of a fish cake type (having an arched cross-section), a conical type or a pyramidal type where the neighborhood of the support 8 is thicker than the circumference.

The grooves 11a and 11b are formed on the top surface 10 of the pedestal 7, which is in the opposite side of the bottom surface 9 contacting the installation surface 13. In the example shown in FIGS. 2 and 3, the grooves 11a and 11b are formed along the back and forth direction of the display device 1. These grooves 11a and 11b are substantially linear with the support 8 located below the central portion of the main body 2 therebetween. Such linearity of the grooves 11a and 11b allows easy insertion of the securing bands and hence stable secured state. Although it is shown in FIG. 3 that the grooves 11a and 11b are formed by one in each side with the support 8 interposed therebetween, they may be formed by two, three, or more in each side with the support 8 interposed therebetween.

As described above, the display device 1 includes the main body 2 having the display panel 4, and the stand 3 having the pedestal 7 and the support 8 for supporting the main body 2, along with the grooves 11a and 11b formed on the top surface 10 of the pedestal 7, which is in the opposite side of the bottom surface 9 contacting the installation surface 13, to position the securing bands 14a and 14b. Thus, the display device 1 can be prevented from falling down by securing the stand 3 of the display device 1 by the securing bands 14a and 14b.

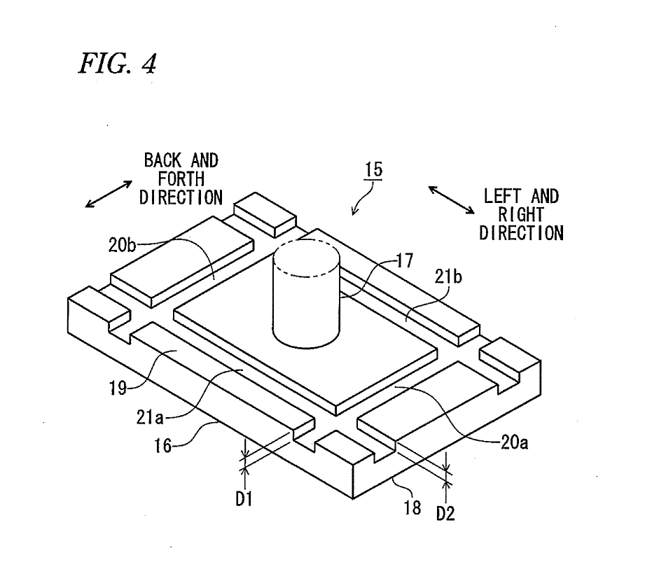

FIG. 4 is a perspective view showing another example of the stand. A stand 15 includes a pedestal 16 and a support 17. The pedestal 16 has a rectangular flat shape and includes the support 17 for supporting the main body 2 in the central portion of the pedestal 16. Grooves 20a, 20b, 21a and 21b are formed on the top surface 19 of the pedestal 16, which is in the opposite side of the bottom surface 18 contacting an installation surface.

In the example shown in FIG. 4, the grooves 20a and 20b are formed along the back and forth direction of the display device 1 and the grooves 21a and 21b are formed along the left and right direction of the display device 1. The grooves 20a and 20b are substantially linear in the back and forth direction with the support 17 interposed therebetween. The grooves 21a and 21b are also substantially linear in the left and right direction with the support 17 interposed therebetween. Although FIG. 4 shows that the grooves are formed by one in each side with the support 17 interposed therebetween, they may be formed by two, three or more in each side with the support 17 interposed therebetween.

The grooves 20a and 20b are formed in the back and forth direction and the grooves 21a and 21b are formed in the left and right direction, and thus the degree of freedom may increase when securing bands are inserted for securing in these grooves. For example, when two securing bands are used, it may be considered to use the grooves 20a and 20b, the grooves 21a and 21b, or the grooves 20a and 21a. As another example, four securing bands may be secured in both of the back and forth direction and the left and right direction, thereby providing stronger secureness.

Although FIG. 4 shows that the depth D1 of the grooves in the back and forth direction is equal to the depth D2 of the grooves in the left and right direction, D1 may be different from D2. For example, if a difference between D1 and D2 is equal to or larger than Tb which is thickness of the securing bands, it is possible to prevent the securing bands in the back and forth direction from contacting the securing bands in the left and right direction at their intersections when the securing bands are secured in both of the back and forth direction and the left and right direction.

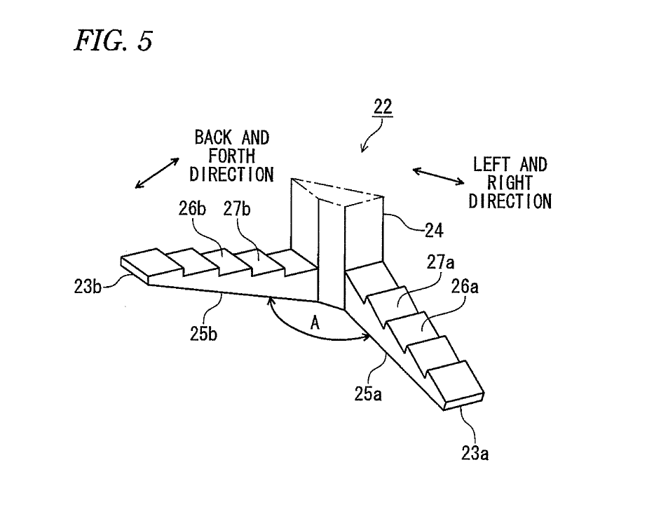

FIG. 5 is a perspective view showing another example of the stand. A stand 22 includes pedestals 23a and 23b and a support 24. In the figure, arrow “A” refers to a fanwise central angle formed by the pedestals 23a and 23b with the support 24 as the center. Steps 27a and 27b are formed on the top surfaces 26a and 26b of the pedestals 23a and 23b, respectively, which are in the opposite side of the bottom surfaces 25a and 25b contacting an installation surface.

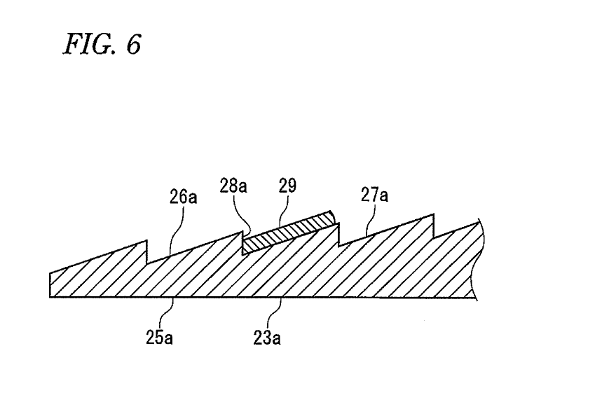

FIG. 6 is a sectional view showing a positional relationship between the pedestal 23a of the stand 22 shown in FIG. 5 and a securing band 29. The securing band 29 is arranged on one step 27a along a slope of the step 27a. The securing band 29 may be positioned by a vertical wall 28a between one step and another, thereby allowing the securing band 29 to be in a stable secured state.

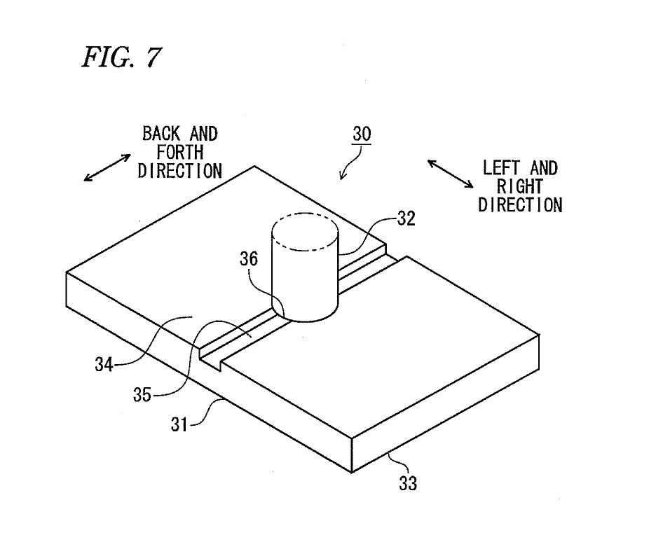

FIG. 7 is a perspective view showing another example of the stand. A stand 30 includes a pedestal 31 and a support 32. The pedestal 31 has a rectangular flat shape and includes the support 32 for supporting the main body 2 in the central portion of the pedestal 31. A groove 35 is formed on the top surface 34 of the pedestal 31, which is in the opposite side of the bottom surface 33 contacting an installation surface.

In the example shown in FIG. 7, the groove 35 is formed along the back and forth direction of the display device 1. The groove 35 is formed just below the support 32. A through hole 36 is formed below the support 32. If the display device 1 is secured by one securing band, the groove 35 may be formed near an intersection of the pedestal 31 and a vertical line passing through the center of gravity of the display device 1. The support 32 is positioned at a portion bearing the overall weight of the main body 2. As the groove 35 is formed just below the support 32, the display device 1 can be secured by one securing band. The groove 35 may be formed in the left and right direction as long as it is formed just below the support 32.

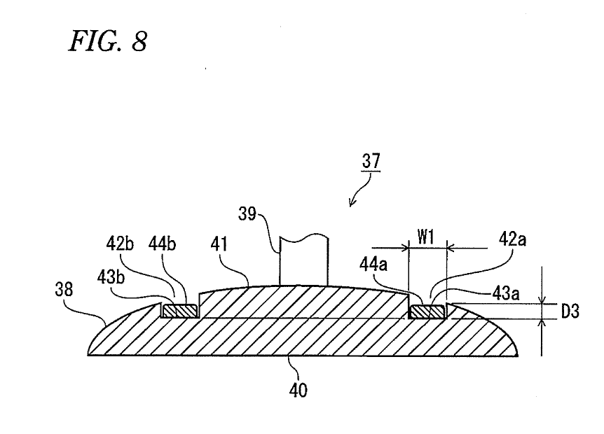

FIG. 8 is a sectional view of a stand for explaining the shape of a groove. A stand 37 includes a pedestal 38 and a support 39. The pedestal 38 includes the support 39 for supporting the main body 2 in the central portion of the pedestal 38. Grooves 42a and 42b are formed on the top surface 41 of the pedestal 38, which is in the opposite side of the bottom surface 40 contacting an installation surface. Securing bands 44a and 44b are disposed within the grooves 42a and 42b, respectively.

Bottom surfaces 43a and 43b of the grooves 42a and 42b may be in parallel to the bottom surface 40 of the pedestal 38 at least in their width direction. Since the tension is evenly exerted in the width direction of the securing bands when the bottom surfaces 43a and 43b at the width direction is in parallel to the bottom surface 40, the securing bands are stably positioned to provide a stable secured state.

The depth D3 from the bottom surfaces 43a and 43b of the grooves 42a and 42b to the top surface 41 of the pedestal 38 may be larger than the thickness of the securing bands. In this case, since the height of a side wall rising from the bottom surfaces 43a and 43b is larger than the thickness of the securing bands, the securing bands will not be taken off. The depth D3 may be 5 mm or more.

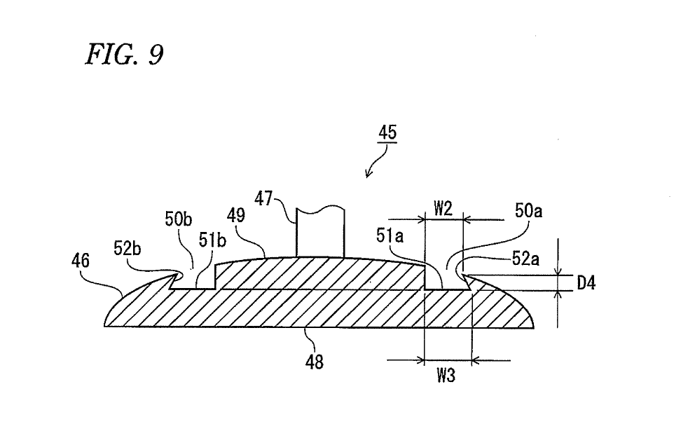

FIG. 9 is a sectional view of a stand for explaining the shape of a groove. A stand 45 includes a pedestal 46 and a support 47. The pedestal 46 includes the support 47 for supporting the main body 2 in the central portion of the pedestal 46. Grooves 50a and 50b are formed on the top surface 49 of the pedestal 46, which is in the opposite side of the bottom surface 48 contacting an installation surface. Securing bands are disposed within the grooves 50a and 50b, respectively.

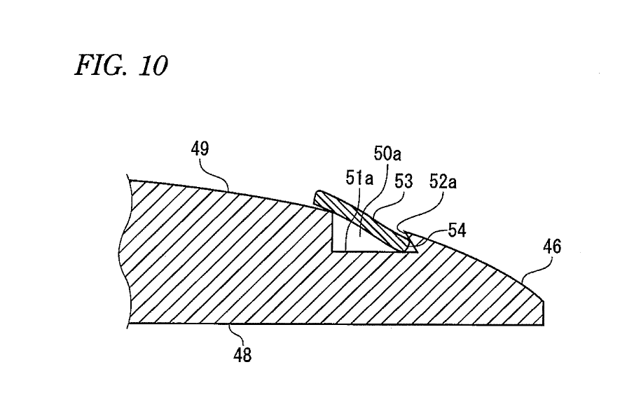

Groove walls 52a and 52b in the outer circumference of the pedestal 46 among groove walls rising from the bottom surfaces 51a and 51b of the grooves 50a and 50b have a wedge shape inclined in a direction in which the bottom surfaces of the grooves are widened. Accordingly, the width W3 of the bottom surfaces 51a and 51b of the grooves 50a and 50b is larger than the width W2 of the grooves at the top surface 49 side. Thus, for example, if the width of the securing bands is larger than W2, the securing bands can be positioned by inserting one end of the securing bands in the width direction below the wedge portion formed in the groove walls 52a and 52b, as shown in FIG. 10.

FIG. 10 is a sectional view showing a state where a band is installed in a groove. Even when the width of a securing band 53 is larger than the width W2 of the grooves at the top surface 49 side, the securing band 53 can be prevented from being separated from the wedge portion formed in the groove wall 52a by inserting one end 54 of the securing band in the width direction below the wedge portion formed in the groove walls 52a.

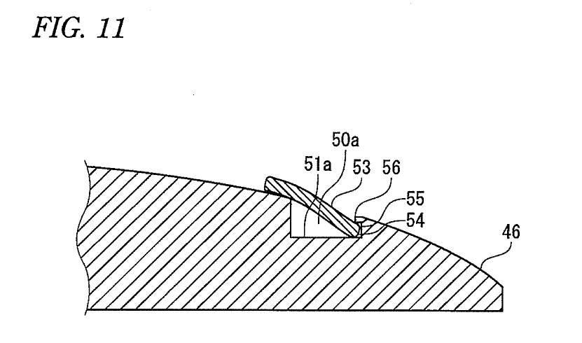

FIG. 11 is a view showing an example of a projection in a groove. A projection 56 is formed in the upper portion of a groove wall 55 in the outer circumference of the pedestal 46 among groove walls rising from the bottom surface 51a of the groove 50a. If the width of the securing band 53 is larger than the width W2 of the groove at the top surface 49 side, the securing band 53 can be prevented from being separated from the projection 56 by inserting one end 54 of the securing band in the width direction below the projection.

While certain embodiments have been described, these embodiments have been presented by way of example only, and are not intended to limit the scope of the invention. Indeed, the novel methods and systems described herein may be embodied in a variety of other forms. Furthermore, various omissions, substitutions and changes in the form of the methods and systems described herein may be made without departing from the sprit of the invention. The accompanying claims and their equivalents are intended to cover such forms or modifications as would fall within the scope and sprit of the invention.

What is claimed is:

1. A display device comprising:
a main body comprising a display panel; and
a stand comprising:
a support configured to support the main body; and
a pedestal having a first surface and a second surface opposite to the first surface, wherein the support is disposed on the first surface of the pedestal, wherein at least one groove is formed on the first surface of the pedestal.

2. The device of claim 1, wherein the at least one groove comprises a plurality of grooves.

3. The device of claim 1, wherein the at least one groove is configured to restrict a position of a securing band for securing the display device to an installation surface on which the display device is installed, when the securing band is provided in the at least one groove.

4. The device of claim 1, wherein a bottom surface of the at least one groove is parallel to the second surface of the pedestal.

5. The device of claim 3, wherein a depth of the groove from the first surface is larger than a thickness of the securing band.

6. The device of claim 1, wherein the groove has an inner side wall and an outer side wall facing an outer periphery of the pedestal, and
wherein an angle between the outer side wall and a bottom surface of the at least one groove is an acute angle.

7. The device of claim 1, wherein the groove has an inner side wall and an outer side wall facing an outer periphery of the pedestal, and
wherein at least one of the inner side wall and the outer side wall has a projection near the first surface of pedestal.
